(19) United States
(12) Patent Application Publication
(10) Pub. No.: US 2026/0202459 A1
(43) Pub. Date: Jul. 16, 2026

(54) METHOD FOR SELECTING A PLURALITY OF TARGET SCAN ROWS ON A WAFER

(71) Applicant: United Semiconductor (Xiamen) Co., Ltd., Xiamen (CN)

(72) Inventors: Zheng Miao Cai, Shamen City (CN); Zhao Te Liu, Shamen City (CN); QINGRONG CHEN, Xiamen (CN); Kai Ping Huang, Tainan City (TW); Chin-Chun Huang, Hsinchu County (TW); WEN YI TAN, Xiamen (CN)

(73) Assignee: United Semiconductor (Xiamen) Co., Ltd., Xiamen (CN)

(21) Appl. No.: 19/048,991

(22) Filed: Feb. 10, 2025

(30) Foreign Application Priority Data
Jan. 14, 2025 (CN) 202510058435.X

(51) Int. Cl. G01R 31/265

(52) U.S. Cl. CPC G01R 31/265

(57) ABSTRACT

A method for selecting a plurality of target scan rows on a wafer, includes performing a selection operation on the wafer to generate a plurality of first scan rows; if an area corresponding to the plurality of first scan rows is greater than a predetermined proportion, performing a first adjustment operation to generate a plurality of second scan rows; performing a uniformity operation on the plurality of second scan rows to generate a plurality of third scan rows; and performing a second adjustment operation according to the plurality of third scan rows to generate the plurality of target scan rows.

### BACKGROUND OF THE INVENTION

### 1. Field of the Invention

The disclosure relates to a method for selecting a plurality of target scan rows on a wafer, and more particularly, a method for selecting a plurality of target scan rows on a wafer to reduce scan areas, test time and associated costs.

### 2. Description of the Prior Art

In the realm of semiconductor manufacturing, multiple dies are often fabricated on a single wafer. Upon completion of fabrication, the wafer undergoes cutting and subsequent packaging procedures to produce individual dies for integration into electronic products. The dies on the wafer are typically arranged in multiple rows, with each row containing several dies. A crucial stage in the die testing process involves testing the dies on the wafer prior to cutting. Comprehensive testing of all dies on the wafer is generally impractical, as it results in prolonged test times and excessively high equipment-related costs, making it uneconomical. Furthermore, current methods predominantly rely on manual expertise for selecting the test areas on the wafer, lacking more automated and reliable solutions. Thus, the selection of appropriate test areas has become a significant challenge within the industry.

### SUMMARY OF THE INVENTION

An embodiment provides a method for selecting a plurality of target scan rows on a wafer. The method includes performing a selection operation on the wafer to generate a plurality of first scan rows; if an area corresponding to the plurality of first scan rows is greater than a predetermined ratio, performing a first adjustment operation to generate a plurality of second scan rows; performing a uniformity operation on the plurality of second scan rows to generate a plurality of third scan rows; and performing a second adjustment operation based on the plurality of third scan rows to generate the plurality of target scan rows.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a diagram of a wafer according to an embodiment.

FIG. 2 shows a flowchart of a method for selecting a plurality of target scan rows on a wafer according to an embodiment.

FIG. 3 and FIG. 4 show a flowchart of a method for selecting target scan rows on a wafer according to another embodiment.

FIG. 5 shows a diagram of adjusting scan rows to improve uniformity according to an embodiment.

FIG. 6 to FIG. 8 show diagrams of adjusting multiple scan rows on the wafer according to an embodiment.

FIG. 9 shows a diagram of a system according to an embodiment.

### DETAILED DESCRIPTION

As used herein, the term “row” refers to a horizontal line. On a wafer, multiple dies are arranged in a horizontal direction to form a row. That is, each row includes multiple dies. Herein, the term “may” indicates that an action is allowed or a feature is present, but the scope of embodiments is not limited thereto. For example, when it is mentioned that a row may include three dies, it means the row is allowed to include, but is not limited to including, three dies. Herein, when a row is “selected”, it indicates that all dies in the row will be tested on the test equipment. The term “scan row” refers to a selected row that will be tested on the test equipment. The term “omitted row” refers to a row that is not selected for testing to reduce test time and costs. The term “delete” scan row refers to canceling the selection of a scan row originally designated for testing and modifying it to an omitted row. The term “move” scan row refers to modifying a scan row to an omitted row and correspondingly modifying another omitted row to a scan row, thus the position of the scan row is considered to be moved.

As used herein, the term “scan area” refers to an area on the wafer that will be tested by the test equipment. The area corresponding to the scan row(s) may be considered the scan area. Herein, a predetermined number of rows may belong to a “reticle area”. For example, each reticle area may include 4 rows of dies, 8 rows of dies, or 9 rows of dies. The number of rows in each reticle area is illustrative, and the specific number of rows may be set as needed. On the same wafer, each reticle area may have the same number of rows. Generally, the wafer is circular. The 12 o'clock direction and the 6 o'clock direction of the wafer may be designated as the top and bottom, respectively, and the 9 o'clock direction and the 3 o'clock direction may be designated as the left and right, respectively. The left-right direction is referred to as the X direction, and the top-bottom direction as the Y direction. When describing the number of elements herein, the term “plurality” or “multiple” refers to more than one, such as two or more.

According to embodiments, scan rows to be tested may be selected from top to bottom by skipping a predetermined number of rows and then selecting at least one row on the wafer. For instance, scan rows to be tested may be chosen from the wafer by skipping 2 rows and then selecting 1 row from top to bottom. In this example, the first and second rows are not selected, and then the third row is selected as a scan row. The fourth and fifth rows are not selected, and the sixth row is selected as a scan row. The seventh and eighth rows are not selected, and the ninth row is selected as a scan row, continuing in this manner. In this example, approximately one-third of the rows on the wafer may be selected as scan rows. Therefore, the scan area of the wafer may be approximately 33%. In other words, about 33% of the dies on the wafer may be tested. The example of “skipping 2 rows and then selecting 1 row” is merely illustrative to explain the principle. The relevant numbers may be adjusted as needed. For example, it can be set to “skipping 3 rows and then selecting 2 rows,” or other configurations, which also fall within the scope of embodiments.

By employing the method, a portion of the rows on the wafer may be selected as scan rows, thus avoiding the need for the test equipment to test all the dies on the wafer. This approach effectively reduces both testing time and costs. However, the method may be further optimized. The following will describe more automated solutions according to embodiments.

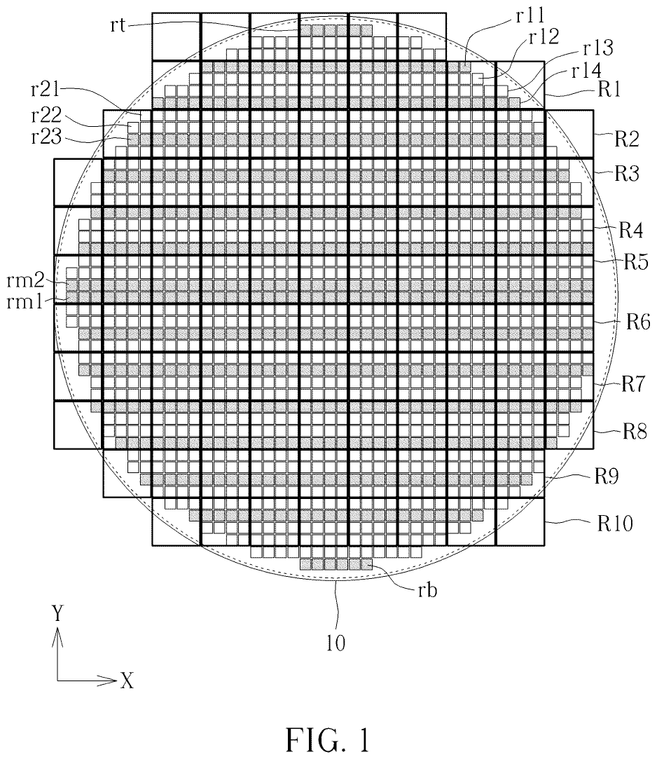

FIG. 1 shows a diagram of a wafer 10 according to an embodiment. Each small square on the wafer 10 may be a die. In FIG. 1, the dies are distributed on the wafer 10, and the wafer 10 has not yet been cut. The wafer 10 may have reticle areas R1 to R10. Each reticle area may have 4 rows in this example. For convenience, the 1st row of the reticle area R1 may be referred to as row r11, the 2nd row of the reticle area R1 may be referred to as row r12, the 3rd row of the reticle area R1 may be referred to as row r13, the 4th row of the reticle area R1 may be referred to as row r14, the 1st row of the reticle area R2 may be referred to as row r21, the 2nd row of the reticle area R2 may be referred to as row r22, and so on. In FIG. 1, the shaded rows may be the selected scan rows. The dies in the scan rows may be tested by the test equipment. The blank rows may be the omitted rows that are not selected. The dies in the omitted rows might be left untested. For example, in FIG. 1, the row r11 and the row r23 are scan rows, while the row r12 is an omitted row. In FIG. 1, the size and arrangement of the dies, the number of reticle areas, the number of rows in each reticle area, and the arrangement of the scan rows and omitted rows are all illustrative, and embodiments are not limited thereto. According to other embodiments, each reticle area may have 8 rows, 9 rows, or any other suitable number of rows.

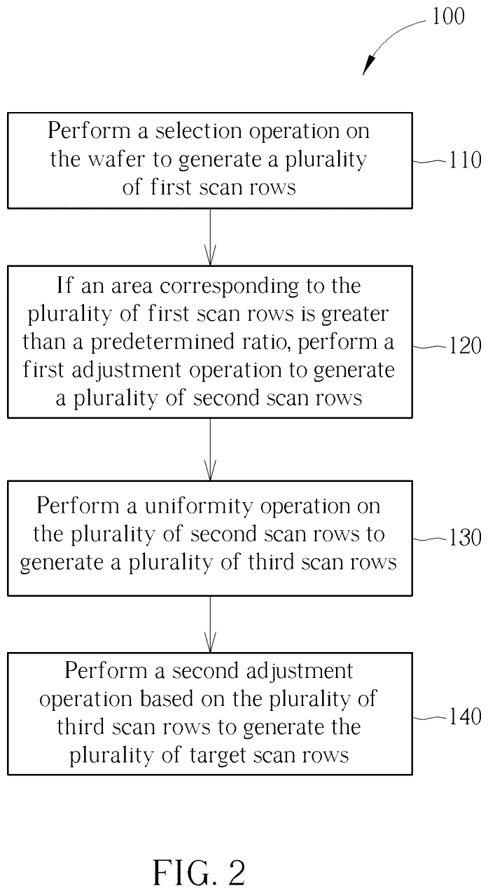

FIG. 2 shows a flowchart of a method 100 for selecting a plurality of target scan rows on a wafer according to an embodiment. The method 100 may include the following steps.

Step 110: Perform a selection operation on the wafer to generate a plurality of first scan rows;
Step 120: If an area corresponding to the plurality of first scan rows is greater than a predetermined ratio, perform a first adjustment operation to generate a plurality of second scan rows;
Step 130: Perform a uniformity operation on the plurality of second scan rows to generate a plurality of third scan rows; and
Step 140: Perform a second adjustment operation based on the plurality of third scan rows to generate the plurality of target scan rows.

The selection operation in Step 110 may be similar to the “skipping 2 rows and then selecting 1 row” operation described above, selecting the plurality of first scan rows on the wafer.

In Step 120, it can be verified whether the area of the plurality of first scan rows exceeds a predetermined ratio of the total area of all rows on the wafer. In Step 120, if the scan area corresponding to the plurality of first scan rows is already less than the predetermined ratio, it indicates that the corresponding testing time and costs are sufficiently low. Therefore, subsequent steps may be unnecessary, and the wafer may be placed on the test equipment for testing. However, if the scan area corresponding to the plurality of first scan rows is still greater than the predetermined ratio, the first adjustment operation may be performed to generate the plurality of second scan rows. The number of second scan rows may not exceed the number of first scan rows.

In Step 130, the uniformity operation may be performed to adjust the positions of the plurality of second scan rows. If the scan rows are spaced too far apart, they can be adjusted closer together to ensure an improved distribution of scan areas across the wafer, preventing both overcrowding and sparse coverage. Following this adjustment, the third set of scan rows can be generated.

In Step 140, a second adjustment operation may be performed to prevent a miss in the reticle areas of the wafer. Herein, the miss may also be referred to as a “reticle area miss”.

The reticle area miss may be explained as follows. Suppose there are 10 reticle areas in the Y direction of the wafer, with each reticle area having 4 rows. In the process, the rows of the reticle areas can be examined to identify which rows are scan rows and which rows are omitted rows.

Based on the requirements, when each reticle area has 4 rows, the scanning pattern should be distributed such that: at least one reticle area has its first row as a scan row, another has its second row as a scan row, another has its third row as a scan row, and yet another has its fourth row as a scan row. This ensures comprehensive coverage across all row positions within the reticle areas. In other words, if none of the first rows across all reticle areas is designated as a scan row, there is a miss at the first row position. In such cases, the first row of the reticle area may be considered a “miss row.”

To generalize, consider a wafer where each reticle area contains n rows. If no reticle area has been assigned a scan row at the i-th row position (where i and n are integers, and 0<i≤n), then a miss occurs at that i-th row position. When this happens, the i-th row of the reticle areas can be designated as a “miss row.” In this case, a reticle area miss has occurred at the i-th row.

The aforementioned reticle area miss will result in poor distribution of the scan areas and die sampling, affecting the subsequent test quality. To resolve this issue, the second adjustment operation in Step 140 may adjust the positions and number of scan rows to generate the target scan rows.

The “target scan rows” produced by the above process are the final result generated by the method 100. The target scan rows may correspond to better scan areas. Subsequently, the target scan rows of the wafer may be tested on the equipment.

When executing the above process to generate the target scan rows, the following principles may be set. The target scan rows should comply with Principles 1 to 3 below. Principles 1 to 3 will be explained in detail as follows.
Principle 1: Select predetermined rows on the wafer as scan rows to generate predetermined scan rows. The target scan rows should include predetermined scan rows.
Principle 2: Each reticle area should have at least one scan row.
Principle 3: If each reticle area has n rows, and none of the i-th rows of all the reticle areas is a scan row, a reticle area miss of the i-th row has occurred. The positions and number of scan rows should be adjusted to deal with the reticle area miss.

The predetermined scan rows mentioned in Principle 1 may include, for example, a topmost scan row of the wafer, a bottommost scan row, a center scan row passing through the center point of the wafer, and an adjacent scan row next to the central scan row. For instance, as shown in FIG. 1, the row rt may be the topmost scan row, the row rb may be the bottommost scan row, the row rm1 may be the central scan row, and the row rm2 may be the adjacent scan row next to the central scan row (i.e. rm1). These four rows may be the predetermined scan rows mentioned in Principle 1. In this example, regardless of how the number and positions of the scan rows are adjusted subsequently, these four rows should ultimately be tested on the test equipment to ensure that the top, bottom, and central parts of the wafer may be tested. The above is an example, and adjustments to the predetermined scan rows based on requirements also fall within the scope of embodiments.

Regarding Principle 2, each reticle area should have at least one scan row. Regarding Principle 3, the reticle area miss should be resolved to avoid uneven sampling distribution. By following Principles 1 to 3, uneven wafer sampling during testing can be prevented. The flow described below will explain how to address these issues.

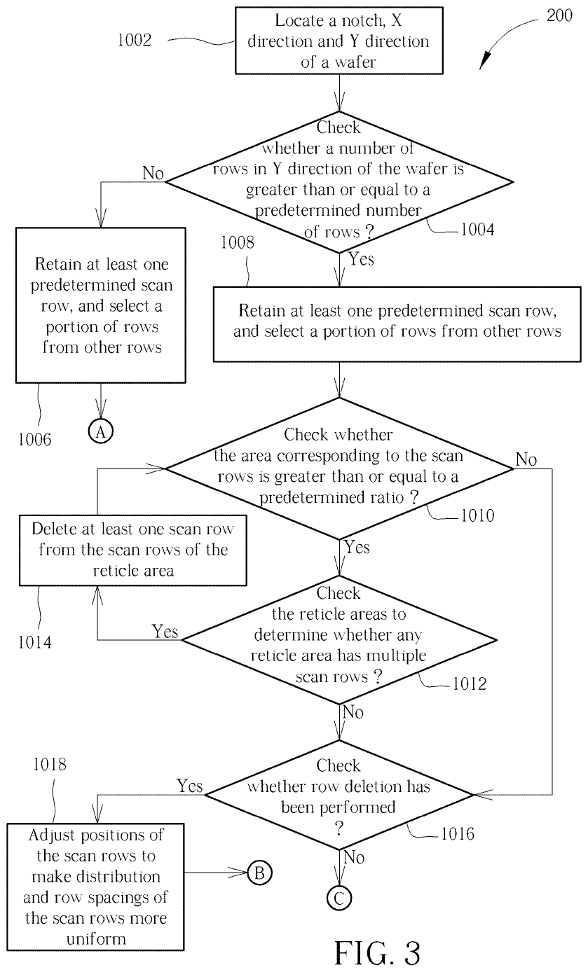

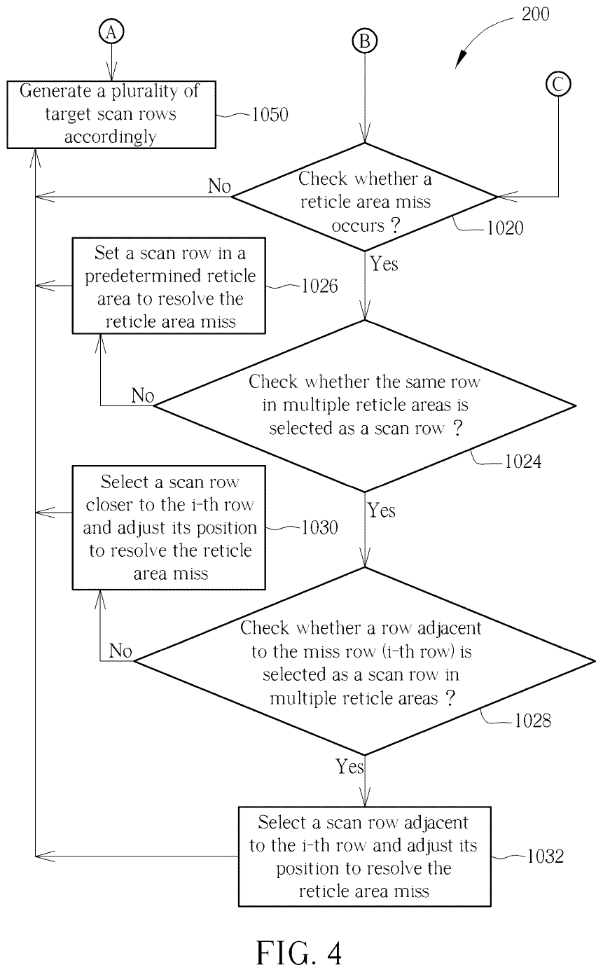

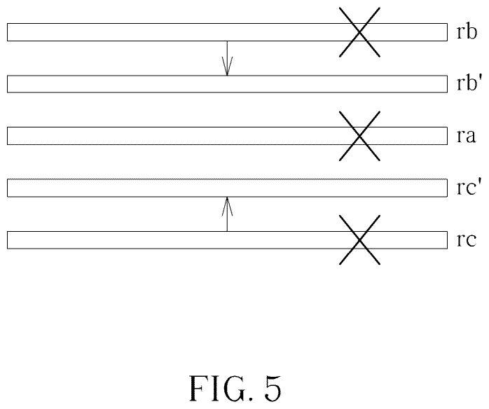

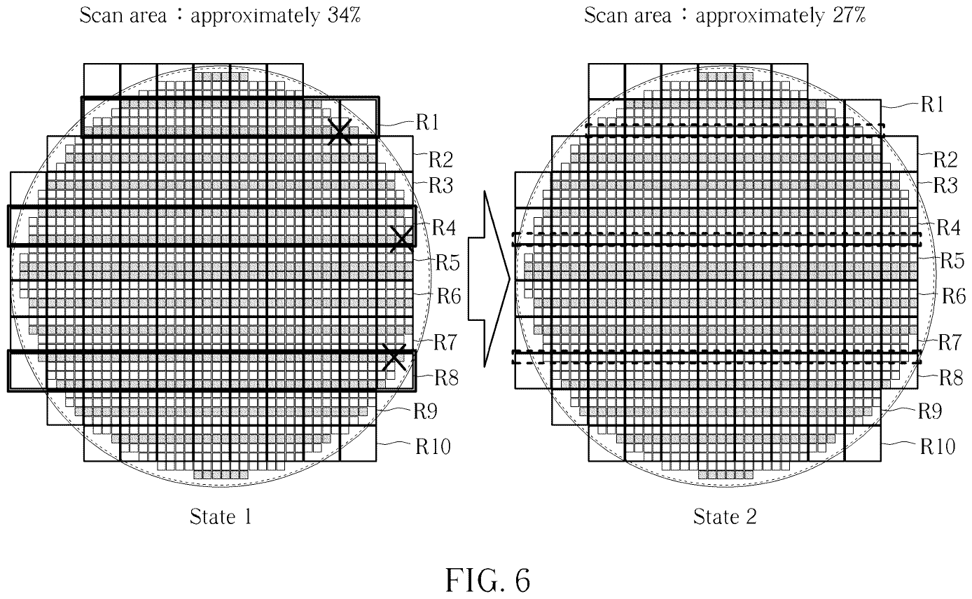

In the following text, a more detailed process is described. FIG. 3 and FIG. 4 show flowcharts of a method 200 for selecting target scan rows on a wafer according to another embodiment. FIG. 5 shows a diagram of adjusting scan rows to improve uniformity. FIG. 6 to FIG. 8 show diagrams of adjusting multiple scan rows on the wafer according to the method 200 in an embodiment. FIG. 6 to FIG. 8 are illustrative, and the number and positions of the scan rows are not limited to those shown in the figures. The steps of the method 200 will be explained with reference to FIG. 6 to FIG. 8 below. After detailing the method 200, FIG. 6 to FIG. 8 will be further explained. In FIG. 6 to FIG. 8, the first row is the “miss row” as an example. When explaining method 200, different rows will be used as miss row examples to facilitate the explanation.

The method 200 may include following steps.

Step 1002: locate a notch, X direction and Y direction of a wafer;
Step 1004: check whether a number of rows in Y direction of the wafer is greater than or equal to a predetermined number of rows? If so, go to Step 1008; if not, go to Step 1006;
Step 1006: retain at least one predetermined scan row, and select a portion of rows from other rows; go to Step 1050;
Step 1008: retain at least one predetermined scan row, and select a portion of rows from other rows; go to Step 1010;
Step 1010: check whether the area corresponding to the scan rows is greater than or equal to a predetermined ratio? If so, go to Step 1012; if not, go to Step 1016;
Step 1012: check the reticle areas to determine whether any reticle area has multiple scan rows? If so, go to Step 1014; if not, go to Step 1016;
Step 1014: delete at least one scan row from the scan rows of the reticle area; go to Step 1010;
Step 1016: check whether row deletion has been performed? If so, go to Step 1018; if not, go to Step 1020;
Step 1018: adjust positions of the scan rows to make distribution and row spacings of the scan rows more uniform;
Step 1020: check whether a reticle area miss occurs? If so, go to Step 1024; if not, go to Step 1050;
Step 1024: check whether the same row in multiple reticle areas is selected as a scan row; if so, go to Step 1028; if not, go to Step 1026;
Step 1026: set a scan row in a predetermined reticle area to resolve the reticle area miss; go to Step 1050;
Step 1028: check whether a row adjacent to the miss row (i-th row) is selected as a scan row in multiple reticle areas? If so, go to Step 1032; if not, go to Step 1030;
Step 1030: select a scan row closer to the i-th row and adjust its position to resolve the reticle area miss; go to Step 1050;
Step 1032: select a scan row adjacent to the i-th row and adjust its position to resolve the reticle area miss; go to Step 1050; and
Step 1050: generate a plurality of target scan rows accordingly.

In the method 200, Step 1004 and Step 1008 may correspond to Step 110 of the method 100. Step 1010, Step 1012, and Step 1014 may correspond to Step 120 of the method 100. Step 1018 may correspond to Step 130 of the method 100. Step 1024, Step 1026, Step 1028, Step 1030, and Step 1032 may correspond to Step 140 of the method 100. Since method 200 comprises decision-making steps, the target scan rows may be generated in Step 1050 without executing all steps of the method 200.

The following describes each step of the method 200. In Step 1002, the notch of the wafer may be located at the edge of the wafer. The notch may be used to locate and align the position of the wafer. For example, the notch may be located at the 6 o'clock position of the wafer.

In Step 1004, the predetermined number of rows is an appropriate quantity. For example, if the predetermined number of rows is 3, when the total number of rows of the wafer in the Y direction is less than 3 rows, proceed to Step 1006.

In Step 1006, the predetermined scan row may be selected as a scan row and should not be set as an omitted row, so the predetermined scan row will be inspected on the test equipment. The predetermined scan row in Step 1006 may include the topmost scan row of the wafer, the bottommost scan row of the wafer, and the middle scan row passing through the center point of the wafer.

The at least one predetermined scan row of Step 1006 may include the topmost scan row, the bottommost scan row, the middle scan row passing through the center point of the wafer, and an adjacent scan row next to the middle scan row (for example, an adjacent row above the middle scan row).

For example, rows other than the predetermined scan row may be selected by skipping 1 row and selecting 1 row from top to bottom in the following sequence: skip 1 row, select 1 row, skip 1 row, select 1 row, and so on. The “skipping 1 row and selecting 1 row” pattern is exemplary, and different numbers of rows may be skipped and selected as needed. Through this operation, rows can be designated as either scan rows or omitted rows. The flow then proceeds to Step 1050 to establish the scan rows as target scan rows for inspection using the test equipment.

Step 1008 operates similarly to Step 1006, where predetermined scan rows can be retained for subsequent inspection on the test equipment, and other rows are either selected or omitted. For example, rows may be selected in a manner of skipping x rows and then selecting y rows. For instance, if x=2 and y=1 (i.e., skipping 2 rows and then selecting 1 row), then other rows, except for the predetermined scan rows, may be selected from top to bottom on the wafer in the manner of skipping 2 rows, selecting 1 row, skipping 2 rows, selecting 1 row, and so on. The aforementioned numbers are merely examples, where x and y here may be integers greater than 0 and may be adjusted as needed. The rows selected in Step 1008 may correspond to the multiple first scan rows described in Step 110 of FIG. 2. In FIG. 6, State 1 may correspond to the result of Step 1008, but the distribution in FIG. 6 is only illustrative, and embodiments are not limited thereto.

On the wafer, rows that are too short are designated as invalid rows. For example, a valid row may include more than 2 dies. When the topmost and bottommost rows include insufficient dies, their adjacent longer rows may be selected as the topmost and bottommost scan rows.

In Step 1010, if the area corresponding to the selected scan rows is greater than or equal to a predetermined ratio of the wafer area, the flow can enter Step 1012. The predetermined ratio in Step 1010 may be set, for example, at 25% (i.e., ¼ of the wafer area), but embodiments are not limited thereto.

In the loop of Steps 1010, 1012, and 1014, each execution may delete only one scan row in Step 1014, and then proceed to Step 1010 for inspection.

Regarding scan row deletion in Step 1014, multiple iterations may be needed. First, delete a scan row from the bottommost reticle area meeting Step 1012 condition. Next, delete a scan row from the topmost reticle area meeting Step 1012 condition. Then delete a scan row from the second reticle area from bottom meeting Step 1012 condition. Next, delete a scan row from the second reticle area from top meeting Step 1012 condition. Then delete a scan row from the third reticle area from bottom meeting Step 1012 condition, and so on. This sequence is exemplary to illustrate the deletion arrangement. The actual number of deletions depends on the flow's requirements and judgment. This alternating top-bottom operation prevents concentrated deletion of rows in either the upper or lower portions of the wafer, maintaining uniform sampling distribution.

In Step 1014, during scan row deletion, at least one of the following rules may be applied.
(Rule 1) For a reticle area including the topmost or bottommost scan row, if it has fewer than 3 scan rows, no rows is deleted from this area.
(Rule 2) For a reticle area including multiple scan rows, the longest scan row may be deleted.
(Rule 3) In the reticle area including the wafer's center, for scan rows of equal length, delete the scan row closest to the center. For two scan rows equidistant from the center, delete the scan row above the center.

Rule 1 can prevent excessive row deletion in the wafer's top and bottom areas to maintain sampling accuracy. Alternatively, Rule 1 may be modified to prohibit any row deletions in reticle areas including the topmost and bottommost scan rows.

Rules 2 and 3 can help reduce the scan area proportion to decrease testing time and cost. These rules are exemplary, and both the rule details and additional rules may be adjusted based on requirements.

The predetermined ratio in Step 1010 may be adjusted based on requirements. If after multiple iterations of Steps 1010, 1012, and 1014, the scan area remains greater than or equal to the predetermined ratio, the predetermined ratio may be adjusted. Alternatively, proceed to Step 1016 either after a set number of iterations or when the scan area approaches the predetermined ratio (e.g., proceeding when scan area is 25.5% and predetermined ratio is 25%, if no further deletions are possible). These approaches are exemplary; appropriate rules may be established according to specific requirements.

If after multiple iterations of Steps 1010, 1012, and 1014 the loop count exceeds a predetermined number, a manual check for abnormalities may be performed. When the area ratio cannot be further reduced or no abnormalities are found, the process may proceed to the next stage.

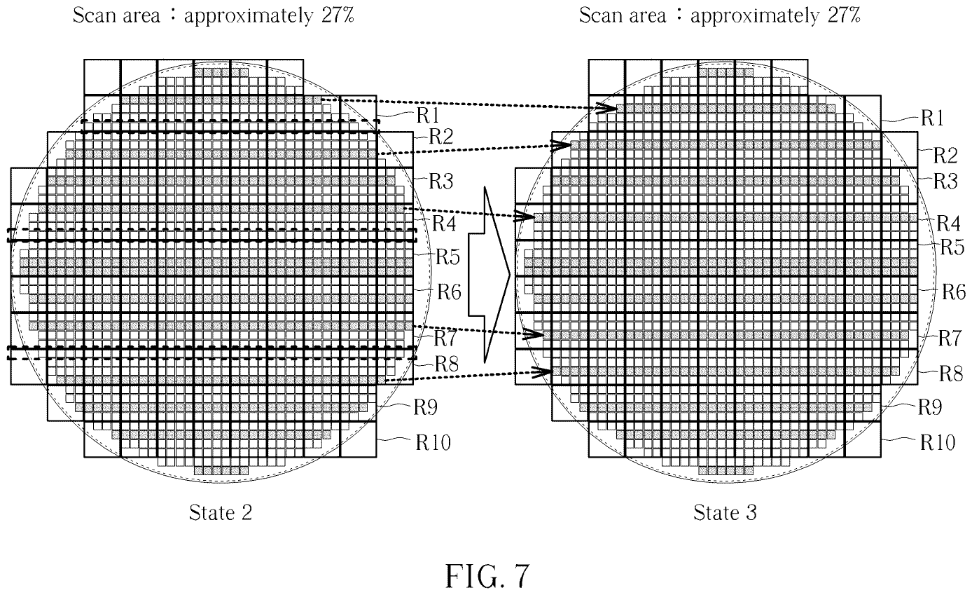

In Step 1016, check whether row deletion occurred in Steps 1010, 1012, and 1014. If no rows were deleted, proceed to Step 1020. If row deletion was executed, proceed to Step 1018. The scan rows in Step 1016 may be the plurality of second scan rows described in Step 120 of FIG. 2. State 2 in FIG. 6 and FIG. 7 may represent the scan row distribution after row deletion in Step 1016. However, FIG. 6 and FIG. 7 are exemplary, and embodiments are not limited thereto.

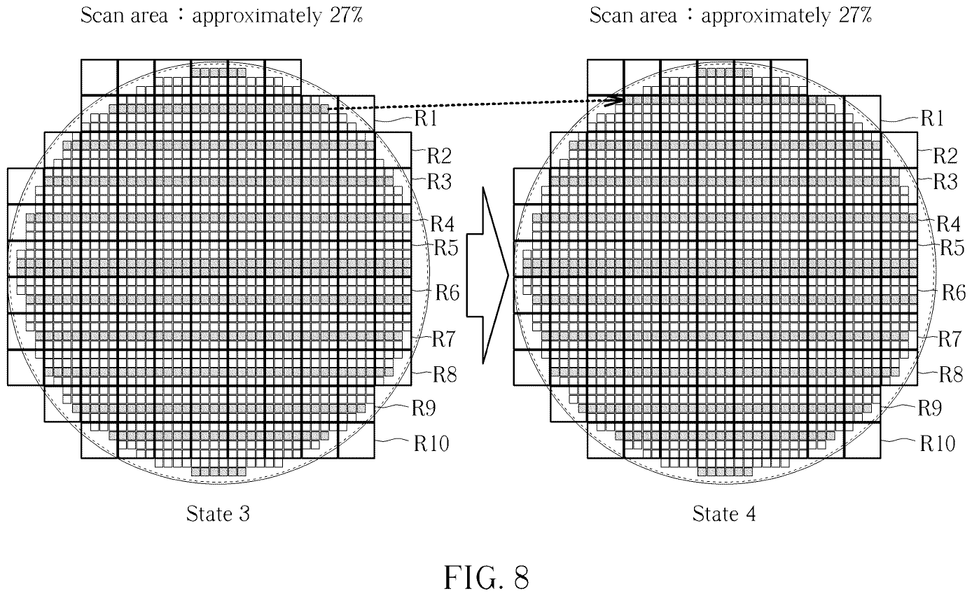

The operation in Step 1018 may be as shown in FIG. 5, which illustrates the adjustment of scan row positions to achieve more uniform distribution and spacing. In FIG. 5, rows marked with “×” indicate deleted scan rows or omitted rows. When a scan row ra is deleted in Step 1014 (becoming an omitted row), a scan row rb above may be changed to an omitted row while a row rb′ below the row rb is selected as a scan row. Similarly, a scan row rc below may be changed to an omitted row while a row rc′ above the row rc is selected as a scan row. This adjustment prevents excessive spacing between original scan rows rb and rc following the row ra's deletion, which would cause uneven distribution. While FIG. 5 shows rows of similar length schematically (not to precise dimensions), actual row lengths may vary by position on a circular wafer. State 3 in FIG. 7 and FIG. 8 may represent Step 1018's result. FIG. 5, FIG. 7, and FIG. 8 are exemplary, and embodiments are not limited thereto.

In Step 1020, check for reticle area miss occurrence. For example, if each reticle area has 4 rows and no second row in any reticle area is selected as a scan row, a reticle area miss of second row has occurred. If no reticle area miss is detected, proceed to Step 1050 to set current scan rows as target scan rows and end the process. If a reticle area miss is found, proceed to Step 1024.

In Step 1024, check whether the same row in multiple reticle areas is selected as a scan row. For example, when a reticle area miss of first row is detected in Step 1020, examine each row's selection count across all reticle areas. For instance, if three reticle areas have their second row selected as a scan row, the second row's selection count can be 3. Similarly, if five reticle areas have their fourth row selected as a scan row, the fourth row's selection count can be 5. For each reticle area including n rows, determine the selection count from first to n-th row and verify if any row has multiple selections in Step 1024.

If Step 1024 result is negative, proceed to Step 1026 to add at least one scan row in the predetermined reticle area (e.g., topmost or bottommost reticle area) to resolve the reticle area miss. For instance, when a reticle area miss of i-th row occurs (no i-th row in any reticle area is selected as a scan row), set the i-th row in the predetermined reticle area as a scan row to resolve the miss and improve scan area distribution.

If Step 1024 is affirmative, proceed to Step 1028 to check whether rows adjacent to the miss row are selected as scan rows in multiple reticle areas. For instance, if the reticle area miss of i-th row occurs, verify whether (i+1)-th row or (i−1)-th row is selected as scan rows in multiple reticle areas.

For example, when a reticle area miss of second row is detected in Step 1020 (indicating no second row in any reticle area is selected as a scan row), check whether adjacent row (one of first and third rows) is selected as scan row in multiple reticle areas.

In this instance, assume three reticle areas have their first row selected as scan rows (selection count of first row is 3) and four reticle areas have their third row selected as scan rows (selection count of third row is 4). Under these conditions, Step 1028 result would be affirmative, leading to Step 1032, where one of these seven scan rows (three first rows and four third rows) would be deleted, and in the same reticle area where the scan row is deleted, move the scan row to the second row (the miss row) to resolve the reticle area miss.

If the first row in the first, third, and fifth reticle areas may be selected as scan rows (first row selection count=3), one of these three reticle areas may be selected. For example, the third reticle area may be selected. In the third reticle area, the first row may be deleted and set as an omitted row, and its second row may be selected as a scan row to resolve the reticle area miss of second row. This operation may be considered as moving the scan row position from first row to second row within the third reticle area.

The above details regarding the numbering and quantities of reticle areas and scan rows, the numbering of miss rows, and the reticle areas with row position adjustments are exemplary, and embodiments are not limited thereto.

In Step 1032, if multiple scan rows are eligible to be moved to resolve the reticle area miss, the longer scan row may be selected to adjust its position and resolve the reticle area miss, thereby achieving better coverage during inspection on the machine.

If Step 1028 is negative (indicating no rows adjacent to the miss row are selected multiple times), proceed to Step 1030. For example, when a reticle area miss of second row occurs, if neither first rows nor third rows are selected multiple times as scan rows in the reticle areas, adjust the scan rows that are both selected multiple times and positioned closer to the second row (miss row) to resolve the reticle area miss.

If multiple reticle areas have their fourth row selected as scan rows, select one of these areas (as fourth row is closer to the second row miss). In the selected reticle area, change the fourth row to an omitted row and set the second row as a scan row to resolve the reticle area miss.

When multiple candidate scan rows may be available and adjusted to resolve the reticle area miss, the longest scan row may be selected. The selected scan row may be changed to an omitted row, and within the same reticle area, the miss row may be set as a scan row to resolve the reticle area miss.

The above row and reticle area numbering are exemplary. Generally, the miss may occur at the i-th row of a reticle area. The operation may move a scan row from (i+αₘᵢₙ)-th row to i-th row to resolve the miss, where αₘᵢₙ may represent the smallest difference between i-th row and its closest multiply-selected row across reticle areas. In the reticle area, a suitable scan row above or below the miss row may be selected for position adjustment to resolve the miss.

In Step 1050, current scan rows may be set as target scan rows for subsequent equipment testing. These target scan rows shall comply with abovementioned Principles 1 to 3. State 4 in FIG. 8 may represent Step 1050's result, showing the target scan rows. However, FIG. 8 is exemplary, and embodiments are not limited thereto.

In Step 1050, after generating the target scan rows, additional adjustments may be performed. The ratio of maximum to minimum row spacing of target scan rows can be generated. If this ratio exceeds a predetermined value, generate a warning message indicating that target scan row positions may require manual adjustment, machine adjustment, or other suitable methods.

This may be expressed by the general formula Γ=β max/β min, where β max is maximum row spacing, β min is minimum row spacing, and Γ is their ratio. A high Γ may indicate non-uniform distribution of target scan rows, triggering a warning message for adjustment. According to an embodiment, a warning message may be issued when Γ≥3.

In the method 200, Step 1010 may set the scan area to be less than a predetermined ratio (e.g., 25% or other suitable ratio) of total area. However, after executing subsequent steps and completing the process in Step 1050, the scan area corresponding to the target scan rows may not be restricted to the predetermined ratio of Step 1010, and a slight increase in the scan area may be permitted due to process execution.

Regarding FIG. 6 to FIG. 8, further explanation is as follows. In FIG. 6, the scan row distribution on the wafer may change from State 1 to State 2. In FIG. 7, the scan row distribution may change from State 2 to State 3. In FIG. 8, the scan row distribution may change from State 3 to State 4. The scan row distribution in State 2 remains consistent between FIG. 6 and FIG. 7, and State 3 distribution remains consistent between FIG. 7 and FIG. 8. Each figure displays consecutive states to illustrate the progression and relationship of scan row changes. States 1 to 4 in FIG. 6 to FIG. 8 are exemplary to demonstrate scan row modifications, and embodiments are not limited thereto.

State 1 scan row distribution may correspond to Step 1008 of the method 200, where predetermined scan rows are retained and additional rows are selected using a pattern of skipping x rows and selecting y rows (e.g., skipping 2 rows and selecting 1 row in top-to-bottom sequence). Under this distribution, the scan area may occupy approximately 34% of the total wafer area.

The scan rows with × marks remain scan rows in State 1 and may be deleted and changed to omitted rows in the above Steps 1010, 1012, and 1014.

In State 2, the scan row distribution may correspond to Step 1016 of the method 200, representing the outcome after row deletion operations performed in Steps 1010, 1012, and 1014. In this example, the scan area corresponding to State 2 scan rows may occupy approximately 27% of the wafer area, indicating a reduction in coverage.

State 3 may correspond to the result of Step 1018 of the method 200 mentioned above. The arrows indicate that the positions of the scan rows have been adjusted to make the distribution more uniform, avoid excessive distance between scan rows, and improve sampling on the wafer. In this example, the scan area corresponding to the scan rows in State 3 may be about 27% of the wafer area.

In State 3, no first row in any reticle area is selected as a scan row, indicating a reticle area miss of first row at this distribution stage.

During the transition from State 3 to State 4, a reticle area miss is resolved by selecting the first row of a reticle area as a scan row. As illustrated in FIG. 8, this resolution is achieved by moving the scan row in reticle area R1 from the second row to the first row.

State 4 may represent the result of Step 1050 of the method 200, where the scan rows may serve as target scan rows. The scan row distribution in State 4 shall comply with Principles 1 to 3 discussed above.

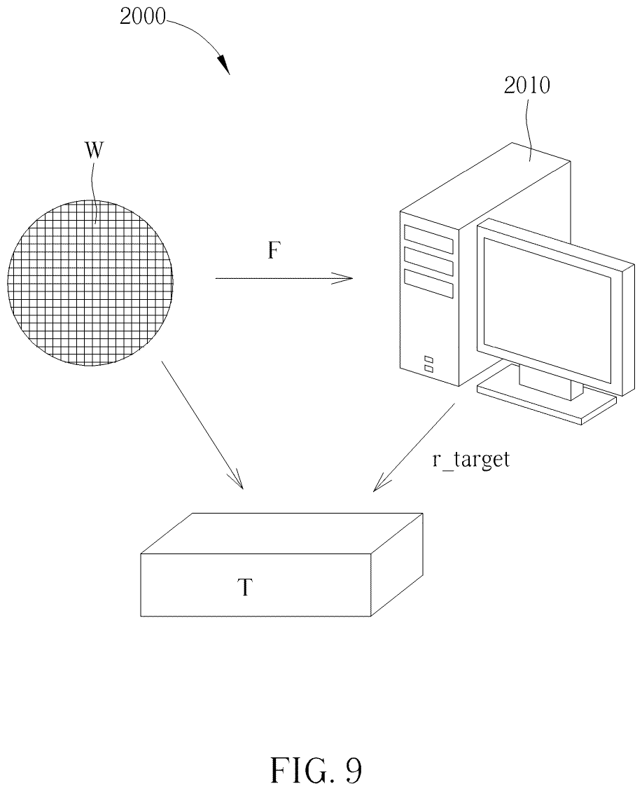

FIG. 9 shows a diagram of a system 2000 according to an embodiment. The feature F of the wafer W may be input into a processing device 2010. The processing device 2010 may execute the above methods 100 and 200 to obtain a plurality of suitable target scan rows r_target. Thereafter, the wafer W may be tested on test equipment T according to the plurality of target scan rows r_target to ensure the quality and yield during mass production of dies, as well as to balance testing efficiency. The processing device 2010 may include at least one of suitable hardware, software, or firmware.

The present disclosure introduces an innovative Area Based Inspection (ABI) system that effectively addresses the limitations of traditional process defect inspection methods, which rely heavily on engineers' experience for manual selection of inspection areas, leading to inconsistencies, resource inefficiencies, and excessive human influence due to varying die sizes of different products. The ABI system automates manual operations by creating customized scan areas and scan schemes tailored to each product, designing more reasonable and uniformly distributed scan schemes based on different inspection area requirements, intelligently distributing inspection points according to layer-specific defects, and utilizing cloud devices for seamless updates of inspection points with a single click, thereby meeting both productivity and quality requirements. The disclosed method automatically calculates the optimal scan scheme based on the scan area, die size, reticle, and the relationship between rows, lines, and areas, following principles of general, basic, balanced, and advanced adjustment, effectively resolving the issues present in traditional inspection methods, enhancing inspection efficiency and accuracy while minimizing resource waste and human interference.

An embodiment provides a method for selecting a plurality of target scan rows on a wafer. The method includes (a) performing a selection operation on the wafer to generate a plurality of first scan rows; (b) if an area corresponding to the plurality of first scan rows is greater than a predetermined ratio, performing a first adjustment operation to generate a plurality of second scan rows; (c) performing a uniformity operation on the plurality of second scan rows to generate a plurality of third scan rows; and (d) performing a second adjustment operation based on the plurality of third scan rows to generate the plurality of target scan rows. For example, this method may correspond to the method 100 in FIG. 2.

According to an embodiment, the abovementioned selection operation may include (a) retaining at least one predetermined scan row on the wafer; and (b) selecting the plurality of first scan rows from a plurality of scan rows other than the at least one predetermined scan row in a manner of skipping x rows and then selecting y rows; where x and y are integers greater than 0. For example, it may correspond to Step 1008 and related steps of the method 200 mentioned above in FIG. 3 and FIG. 4.

According to an embodiment, the at least one predetermined scan row may include a topmost scan row of the wafer, a bottommost scan row, a middle scan row passing through a center point of the wafer, and an adjacent scan row next to the middle scan row. For example, the at least one predetermined scan row may correspond to rows rt, rb, rm1, and rm2 in FIG. 1.

According to an embodiment, the first adjustment operation may include checking a plurality of reticle areas on the wafer to determine whether any of the plurality of reticle areas has a plurality of scan rows. If a reticle area has a plurality of scan rows, at least one scan row from the reticle area may be deleted. For example, it may correspond to Steps 1012 and 1014 and related steps of the method 200 mentioned above.

According to an embodiment, the uniformity operation may include adjusting the plurality of second scan rows to make row spacings between the second scan rows more uniform. For example, it may correspond to Step 1018 and related steps of the method 200 mentioned above.

According to an embodiment, the second adjustment operation may include checking whether a first row to an n-th row of any of a plurality of reticle areas on the wafer is a scan row. If none of i-th rows of the plurality of reticle areas is a scan row, the plurality of third scan rows may be adjusted to set an i-th row in at least one reticle area to a scan row to generate the plurality of target scan rows, where i and n are integers, 0<i≤n. For example, it may correspond to Steps 1020, 1024, 1028, and related steps of the method 200 mentioned above.

According to an embodiment, adjusting the plurality of third scan rows may include setting an i-th row of a predetermined reticle area among the plurality of reticle areas to the scan row. For example, it may correspond to Step 1026 and related steps of the method 200 mentioned above.

According to an embodiment, adjusting the plurality of third scan rows may include following operation. If a j-th row in a first reticle area of the plurality of reticle areas is a scan row, and a j-th row in a second reticle area of the plurality of reticle areas is a scan row, the j-th row in the first reticle area may be removed as a scan row, and setting an i-th row in the first reticle area to be a scan row, where j is an integer, 0<j≤n, and i≠j. For example, it may correspond to Steps 1024 and 1028 and related steps of the method 200 mentioned above.

According to an embodiment, the predetermined ratio may be between 20% and 30%. For example, this predetermined ratio may correspond to the predetermined ratio described in Step 1010 of method 200.

According to an embodiment, the method may further include generating a ratio of a maximum row spacing to a minimum row spacing among the plurality of target scan rows. If the ratio is greater than a predetermined value, a warning message may be generated. For example, it may be related to the aforementioned equation Γ=β max/β min, and the related operations.

In summary, the methods 100 and 200, along with the system 2000, introduced in the embodiments, offer substantial optimization benefits for testing dies on uncut wafers, such as those undergoing chip probe (CP) testing. By employing these methods, the selection of scan rows is optimized through an automated process that reduces the scan area, thereby decreasing testing time and costs while ensuring a more uniform distribution of scan rows. This approach effectively balances the requirements of testing quality and productivity, resulting in the maintenance of excellent testing standards while simultaneously reducing associated costs.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for selecting a plurality of target scan rows on a wafer, comprising:
performing a selection operation on the wafer to generate a plurality of first scan rows;
if an area corresponding to the plurality of first scan rows is greater than a predetermined ratio, performing a first adjustment operation to generate a plurality of second scan rows;
performing a uniformity operation on the plurality of second scan rows to generate a plurality of third scan rows; and
performing a second adjustment operation based on the plurality of third scan rows to generate the plurality of target scan rows.

2. The method of claim 1, wherein the selection operation comprises:
retaining at least one predetermined scan row on the wafer, and
selecting the plurality of first scan rows from a plurality of scan rows other than the at least one predetermined scan row in a manner of skipping x rows and then selecting y rows;
wherein x and y are integers greater than 0.

3. The method of claim 2, wherein the at least one predetermined scan row comprises:
a topmost scan row of the wafer, a bottommost scan row, a middle scan row passing through a center point of the wafer, and an adjacent scan row next to the middle scan row.

4. The method of claim 1, wherein the first adjustment operation comprises:
checking a plurality of reticle areas on the wafer to determine whether any of the plurality of reticle areas has a plurality of scan rows; and
if a reticle area has a plurality of scan rows, deleting at least one scan row from the reticle area.

5. The method of claim 1, wherein the uniformity operation comprises:
adjusting the plurality of second scan rows to make row spacings between the second scan rows more uniform.

6. The method of claim 1, wherein the second adjustment operation comprises:
checking whether a first row to an n-th row of any of a plurality of reticle areas on the wafer is a scan row;
if none of i-th rows of the plurality of reticle areas is a scan row, adjusting the plurality of third scan rows to set an i-th row in at least one reticle area to a scan row to generate the plurality of target scan rows;
wherein i and n are integers, 0<i≤n.

7. The method of claim 6, wherein adjusting the plurality of third scan rows comprises:
setting an i-th row of a predetermined reticle area among the plurality of reticle areas to the scan row.

8. The method of claim 6, wherein adjusting the plurality of third scan rows comprises:
if a j-th row in a first reticle area of the plurality of reticle areas is a scan row, and a j-th row in a second reticle area of the plurality of reticle areas is a scan row, removing the j-th row in the first reticle area as a scan row, and setting an i-th row in the first reticle area to be a scan row;
wherein j is an integer, 0<j≤n, and i≠j.

9. The method of claim 1, wherein the predetermined ratio is between 20% and 30%.

10. The method of claim 1, wherein the method further comprises:
generating a ratio of a maximum row spacing to a minimum row spacing among the plurality of target scan rows; and
if the ratio is greater than a predetermined value, generating a warning message.
